(19) United States
(12) Patent Application Publication
(10) Pub. No.: US 2023/0402389 A1
(43) Pub. Date: Dec. 14, 2023

(54) INTEGRATED WORD LINE CONTACT STRUCTURES IN THREE-DIMENSIONAL (3D) MEMORY ARRAY

(71) Applicant: Intel Corporation, Santa Clara, CA (US)

(72) Inventors: Nanda Kumar Chakravarthi, Fremont, CA (US); Kwame Nkrumah Eason, East Palo Alto, CA (US); Abhinav Tripathi, San Jose, CA (US); Ebony Lynn MAYS, Morgan Hill, CA (US); Jessica Sevanne Kachian, Half Moon Bay, CA (US); Ralf Buengener, San Jose, CA (US)

(21) Appl. No.: 18/235,766

(22) Filed: Aug. 18, 2023

Related U.S. Application Data
(62) Division of application No. 16/681,164, filed on Nov. 12, 2019.

(51) Int. Cl. H01L 23/535; H01L 21/768; H01L 23/528; H01L 23/522; H10B 41/27; H10B 43/27

(52) U.S. Cl. CPC H01L 23/535; H01L 21/76895; H01L 23/5283; H01L 21/76805; H01L 23/5226; H10B 41/27; H10B 43/27

(57) ABSTRACT

A memory array including integrated word line (WL) contact structures are disclosed. The memory array comprises a plurality of WLs that includes at least a first WL and a second WL. An integrated WL contact structure includes a first WL contact and a second WL contact for the first WL and the second WL, respectively. The second WL contact extends through the first WL contact. For example, the second WL contact is nested within the first WL contact. An intervening isolation material isolates the second WL contact from the first WL contact. In an example, the second WL contact extends through a hole in the first WL to reach the second WL. The isolation material isolates the second WL contact from sidewalls of the hole in the first WL.

### BACKGROUND

Flash memory, such as NAND flash memory, is a nonvolatile storage medium. A three-dimensional (3D) flash memory array generally comprises a plurality of word lines (WL) arranged in a staggered or “staircase” manner, such that each WL is at a corresponding specific distance from a top of the memory array. WLs at lower or deeper sections of the staircase are at a relatively longer distance from top of the memory array, compared to WLs at higher or shallower sections of the staircase. A plurality of WL contacts is formed for the corresponding plurality of WLs. As more and more levels of memory cells are packaged within the memory array (i.e., as a number of the WLs increases), the WL contacts extend deeper into the array, to reach the WLs at relatively bottom section of the staircase. Thus, with an increase in the number of levels of memory cells in a modern memory array, aspect ratios of the WL contacts are increasing in order to maintain the same die size. For example, the deeper WL contacts, which are for contacting the WLs at the deeper end of the staircase, have relatively high aspect ratios. There remain a number of challenges with respect to such high aspect ratio WL contacts.

### BRIEF DESCRIPTION OF THE DRAWINGS

FIG. 1 illustrates a cross-sectional view of a memory array comprising a plurality of Word Lines (WL) and a corresponding plurality of WL contacts, wherein a WL contact extends through and is isolated from another WL contact, in accordance with some embodiments of this disclosure.

FIGS. 2A-2C each illustrates an example top-down view of a lateral cross-section of an integrated WL contact structure, in accordance with some embodiments of this disclosure.

FIG. 2D illustrates an example cross-sectional side view of integrated WL contact structures, in which an intervening isolation layer between two WL contacts of an integrated WL contact structure extends up to a bottom portion of an upper WL of a corresponding WL group, in accordance with some embodiments of this disclosure.

FIG. 2E illustrates a perspective view of an integrated WL contact structure of a memory array, in accordance with some embodiments of this disclosure.

FIGS. 3A, 3B illustrate example alignments of WLs in a WL group, in accordance with some embodiments of this disclosure.

FIGS. 4A, 4B illustrate example memory arrays in which an integrated WL contact structure includes WL contacts for more than two WLs, in accordance with some embodiments of this disclosure.

FIGS. 5A, 5B, 5C, 5D, 5E, 5F, 5G, 5H, 5I, 5J, 5K, and 5L collectively illustrate a method for forming integrated WL contact structures for a memory array or other staircased structure, in accordance with some embodiments of this disclosure.

FIG. 6A illustrates a memory array comprising WLs and respective WL contacts, where none of the WL contacts is nested within another WL contact; and FIG. 6B illustrates a memory array comprising WLs and respective WL contacts, where a WL contact is nested within another corresponding WL contact to provide an integrated WL contact structure, in accordance with one or more embodiments of the present disclosure.

FIG. 7 illustrates an example computing system implemented with memory structures disclosed herein, in accordance with one or more embodiments of the present disclosure.

### DETAILED DESCRIPTION

A three-dimensional (3D) memory array is disclosed herein, which includes a plurality of word lines (WL) and a corresponding plurality of WL contacts. In some embodiments, the WLs are arranged in multiple WL groups, each WL group including corresponding two or more WLs. WL contacts for each WL group are nested or otherwise combined to form a corresponding integrated WL contact structure. In an example embodiment where each WL group comprises two WLs (e.g., an upper WL and a lower WL), an integrated WL contact structure comprises an inner WL contact nested within an outer WL contact, with an intervening isolation layer (e.g., comprising dielectric material and/or electrically insulating material) electrically and physically isolating the inner and outer WL contacts. In one such embodiment, the outer WL contact is coupled to the upper WL of the corresponding WL group, and the inner WL contact is coupled to the lower WL of the corresponding WL group. The inner WL contact extends through the outer WL contact, and also extends through a through-hole in the upper WL to reach the lower WL, according to some such embodiments. The inner WL contact is not in physical or electrical contact with the sidewalls of the through-hole in the upper WL, because the intervening isolation layer further isolates the inner WL contact from the sidewalls of the through-hole in the upper WL. Many configurations will be appreciated.

General Overview

As previously discussed herein, there remain a number of challenges with respect to high aspect ratio WL contacts. For instance, etching the deep holes for a relatively deep WL contact is particularly challenging. In more detail, a critical dimension (CD) of a WL contact is a width of the contact measured at a top lateral cross-section of the contact. Increasing the CD of a WL contact results in relatively lower aspect ratio for the WL contact, thereby aiding in the etching process and/or allowing more memory levels to be added. However, the maximum CD of a deepest WL contact is constrained by WL contact pitch, and a minimum-end-to-end (METE) distance between two neighboring WL contacts. To this end, increasing the CD results in an undesirable effect of a corresponding increase in the width of the WL, and hence, an increase in the footprint size of the memory array.

Thus, the present disclosure provides integrated WL contact structures which allow for an increase in the CD of WL contacts, without a corresponding increase in the WL width and/or the memory array size. For example, consider the example case where the WLs of a given memory array are arranged in a staircase fashion, with each WL being at a specific distance from a top of the memory array. In some such embodiments, the WLs are grouped in a plurality of WL groups. Each WL group includes two or more consecutive or neighboring WLs. The WLs of a specific WL group share a corresponding integrated WL contact structure.

For example, assume a WL group comprising a first WL and an adjacent second WL, where the first WL is at a higher level in the staircase than the second WL. Accordingly, the first WL is also referred to herein as a “upper WL” and the second WL is also referred to as a “lower WL” of the WL group, to reflect their relative positions with respect to the staircase. The memory array also comprises a first WL contact for the upper WL, and a second WL contact for the lower WL. In some embodiments, the first and second WL contacts are combined to form an integrated WL contact structure. In some embodiments, the second WL contact is nested within the first WL contact. As the second WL contact is nested within the first WL contact, the first WL contact is also referred to herein as an “outer WL contact,” and the second WL contact is also referred to herein as an “inner WL contact.” In some embodiments, the inner WL contact extends through the outer WL contact, and the two WL contacts are physically and electrically isolated by an intervening isolation layer or isolation structure comprising dielectric and/or insulating material. In some such embodiments, the outer WL contact is in physical contact or coupled to the upper WL, and the inner WL contact extends through a through-hole in the upper WL to reach the lower WL and is in physical contact or coupled to the lower WL. The inner WL contact is not in physical or electrical contact with the sidewalls of the through-hole in the upper WL, as the isolation layer isolates the inner WL contact from the sidewalls of the through-hole in the upper WL.

In some embodiments, a first interconnect feature contacts a top section of the outer WL contact, to couple the outer WL contact with a first routing structure. Similarly, a second interconnect feature contacts a top section of the inner WL contact, to couple the inner WL contact with a second routing structure.

Although the above examples discuss an integrated WL contact structure having two WL contacts, the integrated WL contact structure can include more than two WL contacts as well. In an example where there are three WL contacts in an integrated WL contact structure, the WL contacts can be referred to herein as an outer WL contact, an intermediate WL contact, and an inner WL contact, for an upper WL, an intermediate WL, and a lower WL, respectively. The intermediate WL contact is nested within the outer WL contact, and is isolated from the outer WL contact by a first isolation layer. Similarly, the inner WL contact is nested within the intermediate WL contact, and is isolated from the intermediate WL contact by a second isolation layer. Furthermore, the inner WL contact extends through holes in the upper and intermediate WLs, and is isolated from the sidewalls of the holes by the first and second isolation layers. Also, the intermediate contact extends through the hole in the upper WL, and is isolated from the sidewalls of the hole by the first isolation layer.

As an integrated WL contact structure is shared among the WLs of a WL group, the WLs of the group need not be arranged in a staggered manner relative to each other. In an example, an end of the upper WL can now be substantially aligned with a corresponding end of the lower WL, although the ends of the upper and lower WLs can be staggered in another example. Thus, note that a typical staircase architecture is not needed, according to some embodiments, although other embodiments may include a typical staircase architecture.

Because the inner WL contact is nested within the outer WL contact, the outer WL contact has a higher width and a higher CD, than it would have been if the WL contacts were separated and stand-alone WL contacts. Thus, the integrated WL contact structure allows for a higher CD of the outer WL contact. The increase in the CD of the outer WL contact does not come at an expense of increasing the WL width or any increase in the memory array size. Rather, the increase in the CD of the outer WL contact is at least partly due to extending the inner WL contact through the outer WL contact.

The increase in the CD results in a corresponding decrease in an aspect ratio for the outer WL contact, which aids in the WL contact formation process. For example, as discussed herein in further details, the outer WL contact is formed by etching a hole within the memory array dielectric. As the outer WL contact has a larger CD and a lower aspect ratio, the etching of the hole, while forming the outer WL contact, is relatively easy. As merely one integrated WL contact per two WLs are formed, in an example, up to 1.5 times (1.5×) stair width can now be utilized for the etch operation when forming the outer WL contact. The larger CDs of even the deeper WL contacts lead to faster etch of deepest contacts, which results in faster process time and higher margin for the WL contact etch operation to fabricate the memory array, without any corresponding increase in the memory array size.

As discussed herein, terms referencing direction, such as upward, downward, vertical, horizontal, left, right, front, back, etc., are used for convenience to describe example embodiments of integrated circuits depicted in a certain orientation. Embodiments of the present disclosure are not intended to be limited by these directional references.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

Note that, as used herein, the expression “X includes at least one of A or B” refers to an X that may include, for example, just A only, just B only, or both A and B. To this end, an X that includes at least one of A or B is not to be understood as an X that requires each of A and B, unless expressly so stated. For instance, the expression “X includes A and B” refers to an X that expressly includes both A and B. Moreover, this is true for any number of items greater than two, where “at least one of” those items are included in X. For example, as used herein, the expression “X includes at least one of A, B, or C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, or C is not to be understood as an X that requires each of A, B, and C, unless expressly so stated. For instance, the expression “X includes A, B, and C” refers to an X that expressly includes each of A, B, and C. Likewise, the expression “X included in at least one of A or B” refers to an X that may be included, for example, in just A only, in just B only, or in both A and B. The above discussion with respect to “X includes at least one of A or B” equally applies here, as will be appreciated.

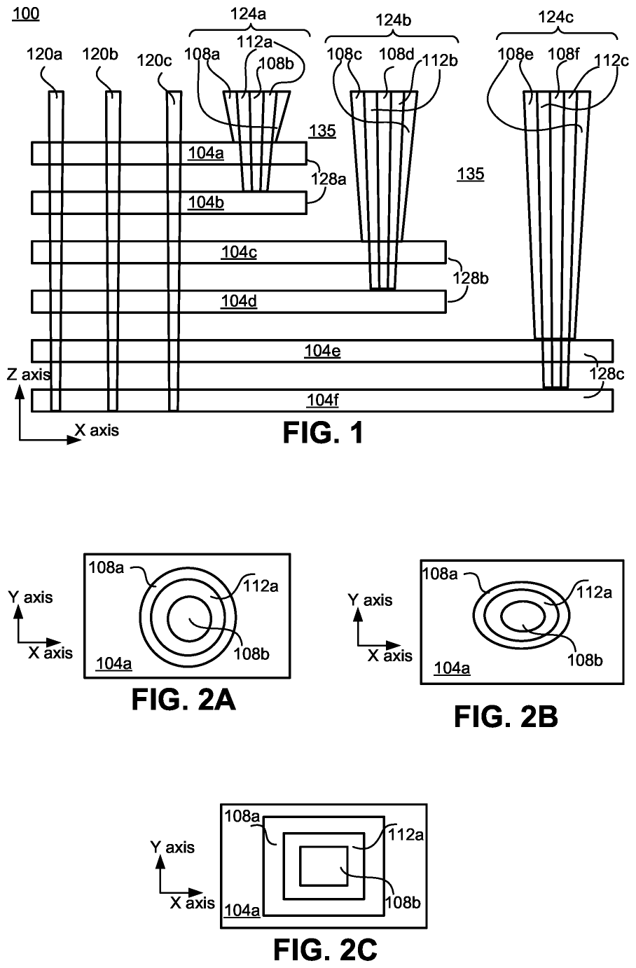

Elements referred to herein with a common reference label followed by a particular number or alphabet may be collectively referred to by the reference label alone. For example, WLs 108a, . . . , 108f of FIG. 1 may be collectively and generally referred to as WLs 108 in plural, and WL 108 in singular.

Architecture and Methodology

FIG. 1 illustrates a cross-sectional view of a memory array (also referred to as an “array”) 100 comprising a plurality of Word Lines (WL) 104a, . . . , 104f and a corresponding plurality of WL contacts 108a, . . . , 108f, wherein a WL contact (e.g., WL contact 108b) extends through and is isolated from a corresponding WL contact (e.g., WL contact 108a), in accordance with some embodiments of this disclosure.

In an example, the array 100 comprises any appropriate 3D memory array, such as a floating gate flash memory array, a charge-trap (e.g., replacement gate) flash memory array, a phase-change memory array, a resistive memory array, an ovonic memory array, a ferroelectric transistor random access memory (FeTRAM) array, a nanowire memory array, a 3D NAND memory, a 3D NOR memory, or any other 3D memory array. In one example, the memory array 100 is a stacked 3D NAND flash memory array, which stacks multiple floating gates or charge-trap flash memory cells in a vertical stack wired in a NAND (not AND) fashion. In another example, the 3D memory array 100 includes 3D NOR (not OR) storage cells. Although merely six WLs 104a, . . . , 104f are illustrated for the array 100, the array 100 can have any appropriate number of WLs.

In some embodiments, the array 100 includes one or more pillars, such as pillars 120a, 120b, 120c. Although merely three pillars 120 are illustrated, the array 100 can have any other appropriate number of pillars, such as one, two, four, or higher. Individual charge storage device (e.g., memory cell, not illustrated) is formed at or near a corresponding junction of a corresponding WL and a corresponding pillar. Thus, a plurality of memory cells is formed in the array 100, in a plurality of locations defined by junctions of individual pillars and individual WLs. The pillars 120a, 120b, 120c are also referred to herein as memory pillars.

In one example, a WL 108 couples a plurality of memory cells. For example, a plurality of memory cells, which are formed at or near the junctions of the WL 108a and the various pillars 120a, 120b, 120c, are coupled by the WL 108a. The charge storage devices coupled by the same WL can be logically grouped into a memory page. In some embodiments, the WLs 108 comprise conductive material, such as tungsten, polysilicon, an appropriate metal, and/or any appropriate conductive material.

The array 100 is illustrated in high level in FIG. 1, without illustrating various components within the array 100. For example, although not illustrated, the array 100 includes, or is coupled to, one or more logic circuitry comprising logic components such as address decoders, state machines, buffers, word line drivers, bit line drivers, sense amplifiers, voltage dividers, charge pumps, digital logic blocks, logic gates, switches, inverters, adders, multipliers, and/or any other appropriate component of a memory array logic circuitry. Similarly, although not illustrated, the array 100 includes various conductive access lines to enable access to the memory cells, such as bitlines, select gate source (SGS), and select gate drain (SGD), current common source (SRC, also referred to as a source plate), and/or any other appropriate memory access line.

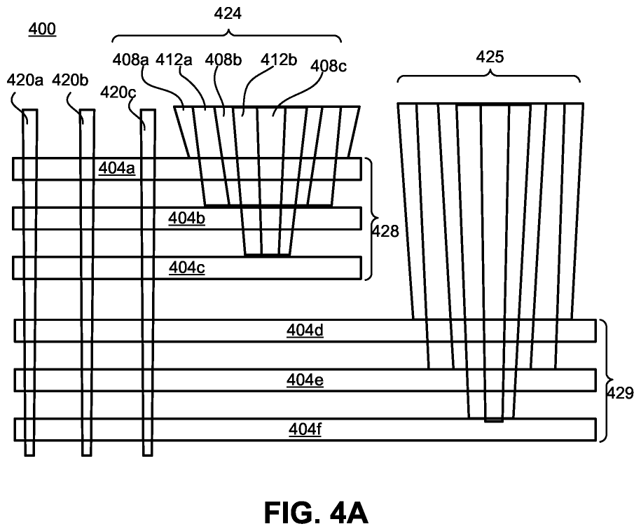

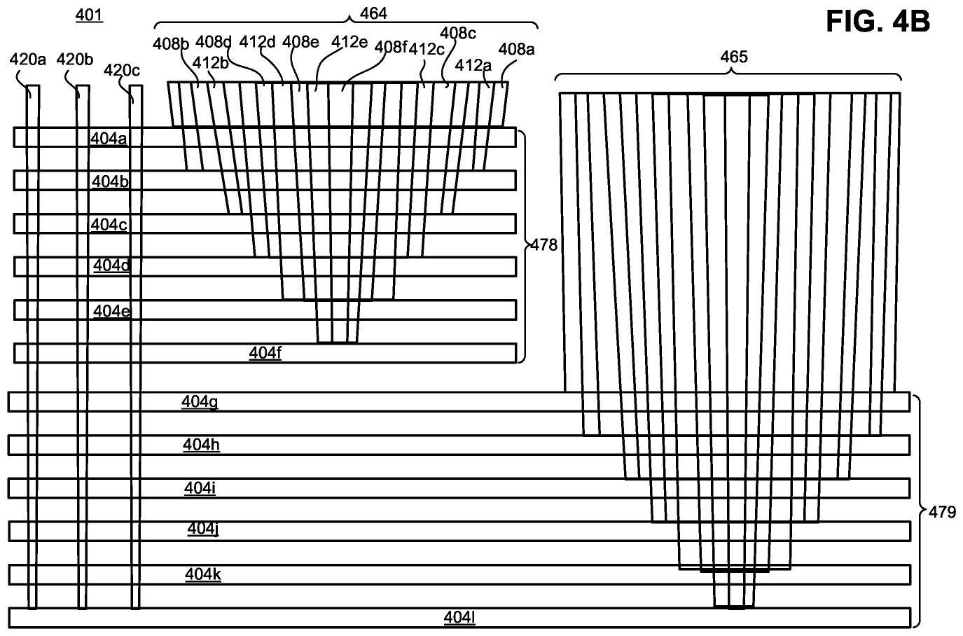

In some embodiments, the WLs 104 are grouped in multiple groups. For example, the WLs 104a, 104b are grouped in a first group 128a, the WLs 104c, 104d are grouped in a second group 128b, and the WLs 104e, 104f are grouped in a third group 128c. Although in FIG. 1 each WL group comprises two WLs, the teachings of this disclosure are not intended to be so limited, and a WL group can include more than two WLs, such as three WLs (e.g., as discussed with respect to FIG. 4A), or a higher number of WLs (e.g., as discussed with respect to FIG. 4B). Thus, each WL group comprises two or more WLs.

The WLs of each WL group share WL contacts of a corresponding integrated WL contact structure. For example, the WL contacts of the WL group 128a are combined to form an integrated WL contact structure 124a, the WL contacts of the WL group 128b are combined to form an integrated WL contact structure 124b, and the WL contacts of the WL group 128c are combined to form an integrated WL contact structure 124c.

The integrated WL contact structure 124a has a WL contact 108b nested within another WL contact 108a, and separated by intervening isolation layer or isolation structure 112a (also referred to herein as isolation material 112). In an example, the isolation layer 112 comprises dielectric material and/or electrically insulating material. For example, the integrated WL contact structure 124a has the WL contact 108b that extends through the WL contact 108a, and also extends through the WL 104a. For example, the WL contact 108b is coupled (e.g., connected) to the WL 104b, and the WL contact 108a is coupled (e.g., connected) to the WL 104a. For example, the WL contact 108b is physically attached to the WL 104b, and the WL contact 108a is physically attached to the WL 104a. In some embodiments, the WL contact 108b contacts the WL 104b, and is electrically coupled to the WL 104b. Thus, the WL contact 108b acts as a contact for the WL 104b, and external logic circuitries communicate with the WL 104b through the WL contact 108b. Similarly, the WL contact 108a contacts the WL 104a, and is electrically coupled to the WL 104a. Thus, the WL contact 108a acts as a contact for the WL 104a, and external logic circuitries communicate with the WL 104a through the WL contact 108a.

The WL contact 108b extends through the WL 104a, and the WL contact 108b is separated from the WL 104a by the isolation layer 112, which is also referred to herein as isolation material 112a. For example, the WL 104a has an opening or through-hole, and the WL contact 108b extends through the through-hole of the WL 104a. The WL contact 108b does not touch the sidewalls of the through-hole of the WL 104a. For example, the WL contact 108b is separated from the sidewalls of the through-hole of the WL 104a by the isolation material 112a. Thus, the isolation material 112a also extends through the through-hole of the WL 104a, and is in contact with the sidewalls of the through-hole of the WL 104a. The isolation material 112a also separates and isolates the WL contact 108b from the WL contact 108a. Thus, the isolation material 112a physically and electrically isolates the WL contact 108b from the WL 104a and the WL contact 108a.

Thus, for example, the WL contact 108b is nested within another WL contact 108a. The inner WL contact 108b resides inside the outer WL contact 108a, and the two WL contacts are electrically and physically isolated from each other by the isolation material 112a. The outer WL contact 108a is in electrical and physical contact with the upper WL 104a, and the inner WL contact 108b is in electrical and physical contact with the lower WL 104b. The inner WL contact 108b extends through a hole in the upper WL 104a. The inner WL contact 108b is physically and electrically isolated from the upper WL 104a and the outer WL contact 108a by the isolation material 112a. As illustrated, a length of the inner WL contact 108b is greater than a length of the outer WL contact 108a.

Although in FIG. 1 the space between the integrated WL contact structures 124a, 124b, 124c are shown as empty, in an example, at least sections of the space between the integrated WL contact structures 124a, 124b, 124c are occupied by appropriate dielectric and/or insulating material 135 (such as an appropriate oxide), which electrically and physically separate the various integrated WL contact structures 124a, 124b, 124c.

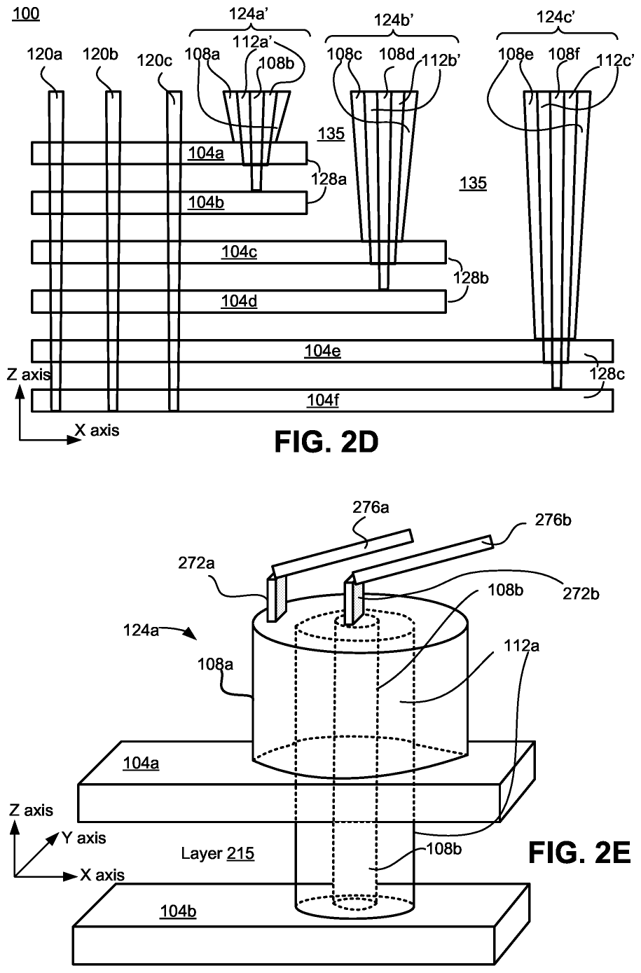

FIGS. 2A-2C each illustrates an example top-down view of a lateral cross-section of the integrated WL contact structure 124a, in accordance with some embodiments of this disclosure. As can be seen in each of FIGS. 2A-2C, each WL structure 104a includes an inner WL contact 108b that extends through an outer WL contact 108a, with the outer WL contact 108a being separated from the inner WL contact 108a by isolation material 112a. However, there are some differences between the example embodiments shown. In the example of FIG. 2A, the cross-section of the WL contacts 108a and 108b are substantially circular. Thus, in this example, the WL contacts 108a and 108b can be imaged (e.g., such as by cross-sectional scanning electron microscope or other imaging gear) as concentric tapered cylinders, separated by the isolation material 112a. In some embodiments, the cylinders are tapered such that the cylinders have a relatively higher width at the top compared to the width at the bottom, e.g., see FIG. 1. In the example of FIG. 2B, the cross-section of the WL contacts 108a and 108b are substantially oval shaped. In the example of FIG. 2C, the cross-section of the WL contacts 108a and 108b are substantially rectangular shaped. As will be appreciated in light of this disclosure, the cross-sectional shape of the WL contacts 108a, 108b can vary, for instance, based on the forming techniques used.

Referring again to FIG. 1, the isolation layer 112a extends down to the WL 104b, the isolation layer 112b extends down to the WL 104d, and so on. However, in some example embodiments, the isolation layer 112a can extend merely down to a bottom portion of the WL 104a, the isolation layer 112b can extend merely down to a bottom portion of the WL 104c, and so on, as illustrated in FIG. 2D. FIG. 2D illustrates integrated WL contact structures 124′, in which an intervening isolation layer 112′ between two WL contacts (e.g., isolation layer 112a′ between WL contacts 108a, 108b) of an integrated WL contact structures 124′(such as integrated WL contact structures 124a′) extends down to a bottom portion of an upper WL (e.g., WL 104a) of a corresponding WL group (e.g., WL group 128a), in accordance with some embodiments of this disclosure. Thus, the isolation layer 112a′ extends through the WL 104a and ends at a bottom section of the WL 104a. Note that the isolation layer 112a′ is still able to physically and electrically isolate the inner WL contact 108b from (i) sidewalls of the hole in the upper WL 104a, and (ii) the outer WL contact 108a.

FIG. 2E illustrates a perspective view of an integrated WL contact structure 124 of a memory array (such as memory array 100 of FIG. 1), in accordance with some embodiments of this disclosure. For example, FIG. 2E illustrates the WLs 104a, 104b, and the integrated WL contact structure 124 comprising the WL contacts 108a, 108b and intervening isolation layer 112a. The WL contacts 108a, 108b and the isolation layer 112a are illustrated as concentric cylinders in FIG. 2E, having somewhat circular or oval shaped cross section, as discussed with respect to FIGS. 2A-2B. In FIG. 2E, the isolation layer 112a extends until the bottom section of WL 104a, as discussed with respect to FIG. 1, thereby electrically and physically isolating the WL contact 108b from both the WL contact 108a and the WL 104a.

Also labelled in FIG. 2E is a layer 215 comprising insulating material, which is between any two neighboring WLs. For example, the layer 215 is present between WL 104a and 104b, between WL 104b and 104c, and so on, although the layer 215 in not labelled in FIG. 1. The layer 215 is an insulating layer comprising appropriate insulating material, such as an oxide material (e.g., silicon oxide, carbon doped oxide, or another appropriate oxide material), an oxynitride material (e.g., silicon oxynitride), and/or a nitride material (e.g., silicon nitride), and is also referred to as a tier oxide layer.

Also illustrated in FIG. 2E are contact terminals 272a, 272b for the WL contacts 108a, 108b, respectively. For example, the contact terminals 272a, 272b are vias that respectively couple the WL contacts 108a, 108b to outside circuitries. In such cases, note that routing layers 276a, 276b are respectively coupled to the contact terminals 272a, 272b. The contact terminals 272a, 272b and/or the routing layers 276a, 276b comprise conductive material, such as an appropriate metal. The routing layers 276a, 276b communicate signals between the WLs 104a, 104b and external components (such as logic circuitry for reading from and/or writing to the memory array 100).

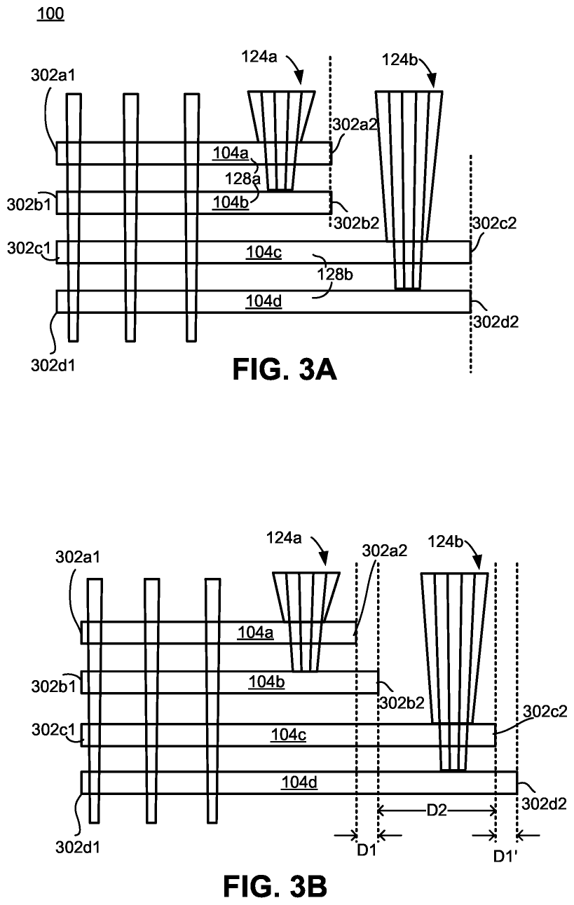

FIGS. 3A, 3B illustrate example alignments of WLs in a WL group, in accordance with some embodiments of this disclosure. For purposes of illustrative clarity, in each of FIGS. 3A-3B, merely the WL group 128a comprising the WLs 104a, 104b, and the WL group 128b comprising the WLs 104c, 104d are illustrated, without illustrating the third WL group 128c.

In an example, each WL 104 has a first end and an opposing second end, where the pillars extends through a first section of the WL near the first end, and a corresponding WL contact makes contact with a second section of the WL near the second end. In FIGS. 3A, 3B, the first ends of the WLs 104a, 104b, 104c, 104d are respectively labelled as 302a 1, 302b1, 302c1, and 302d1. Similarly, the second ends of the WLs 104a, 104b, 104c, 104d are respectively labelled as 302a2, 302b2, 302c2, and 302d2.

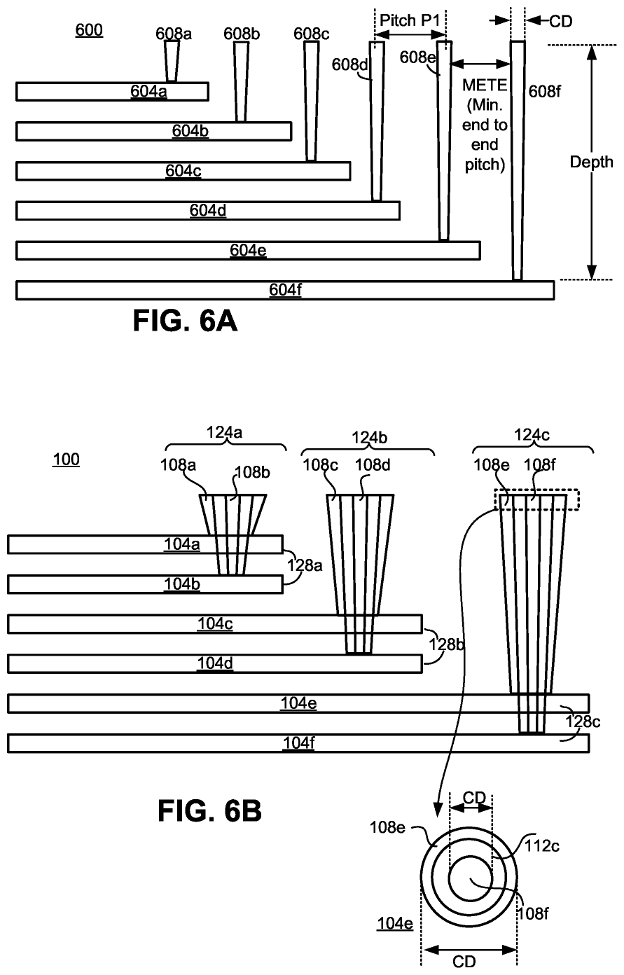

In the example of FIG. 3A, for the WL group 128a comprising the WLs 104a, 104b, the second ends 302a2 and 302b2 are substantially aligned. Similarly, for the WL group 128b comprising the WLs 104c, 104d, the second ends 302c2 and 302d2 are substantially aligned. In contrast, in a 3D memory array that does not have the integrated WL contact structures (e.g., as illustrated herein later in FIG. 6A), all word lines are staggered or arranged in a stair-case like pattern, such that no two WLs have substantial alignment at their second ends. However, because a single integrated WL contact structure is used in the memory array of FIG. 3A for multiple WLs of a WL group, the second ends of the multiple WLs of a WL group can now be substantially aligned.

In the example of FIG. 3B, for the WL group 128a comprising the WLs 104a, 104b, the second ends 302a2 and 302b2 are misaligned by a length D1. Similarly, for the WL group 128b comprising the WLs 104c, 104d, the second ends 302c2 and 302d2 are misaligned by a length D1′ (which may be equal to D1). Also, the second ends 302b2, 302c2 of the WLs 104b, 104c, respectively, are misaligned by a distance D2. In some embodiments, D2 is relatively higher than D1 and D1′, e.g., by a factor of 5×, 10×, 20×, or higher. The misalignment D1 (or D1′) may be intentional, or may be an unintended consequence of process or equipment limitations attendant the WL formation process.

Note that the distance D1 and D1′ of FIG. 3B is substantially zero in FIG. 3A, where substantially zero implies that the distance D1 is less than a threshold value, such as 1 nm, 2 nm, nm, 10 nm, or the like.

In a 3D memory array that does not have the integrated WL contact structures (e.g., as illustrated herein later in FIG. 6A), all word lines are staggered or arranged in a stair-case like pattern, with substantially similar misalignment between two neighboring word lines. In contrast, due to the integrated WL contact structures 124 of FIG. 3B, a misalignment between two neighboring WLs in FIG. 3B depends on whether the two WLs belong to the same WL group, or to two different WL groups.

In FIGS. 1-3B, an integrated WL contact structure 124 includes WL contacts for corresponding two WLs. However, the teachings of this disclosure are not intended to be limited to an integrated WL contact structure including WL contacts for merely two WLs. For example, FIG. 4A illustrates a memory array 400 in which an integrated WL contact structure 424 includes WL contacts for more than two WLs, in accordance with some embodiments of this disclosure. For example, in the example of FIG. 4A, the integrated WL contact structure 424 includes WL contacts for three WLs 404a, 404b, 404c, and the integrated WL contact structure 425 includes WL contacts for three WLs 404d, 404e, 404f. For example, FIG. 4A illustrates a WL group 428 including the three WLs 404a, 404b, 404c, and a WL group 429 including the three WLs 404d, 404e, 404f, although each WL group can include more than three WLs. The array 400 is likely to include several such WL groups, although merely two WL groups 428, 429 are illustrated for purposes of illustrative clarity. Also illustrated in FIG. 4A are the pillars 420a, 420b, 420c.

In some embodiments, the integrated WL contact structure 424 has WL contacts 408a, 408b, and 408c for WL 404a, 404b, and 404c, respectively. For example, the WL contact 408c extends through the WL contact 408b, and the WL contacts 408b extends through the WL contact 408a. Furthermore, the WL contacts 408b, 408c extend through the WL 404a, and the WL contact 408c extends through the WL 404b. As illustrated in FIG. 4A, isolation material 412a electrically and physically isolates the WL contact 408b from the WL contact 408a and the WL 404a. Similarly, isolation material 412b electrically and physically isolates the WL contact 408c from the WL contact 408b and the WL 404b. Thus, the WL contact 408c is nested within the WL contact 408b, and the WL contact 408b is nested within the WL contact 408a. The integrated WL contact structure 425 has similar structure, although individual components of the integrated WL contact structure 425 are not labelled in FIG. 4A for purposes of illustrative clarity.

FIG. 4B illustrates a memory array 401 in which an integrated WL contact structure 464 includes WL contacts for more than two WLs, in accordance with some embodiments of this disclosure. For example, in the example of FIG. 4B, the integrated WL contact structure 464 includes WL contacts for six WLs 404a, 404b, 404c, 404d, 404e, and 404f, and the integrated WL contact structure 465 includes WL contacts for six WLs 404g, 404h, 404i, 404j, 404k, and 4041. For example, FIG. 4B illustrates a WL group 478 including the six WLs 404a, . . . , 404f, and a WL group 479 including the six WLs 404g, . . . , 4041, although each WL group can include more (or less) than six WLs, such as seven, eight, or higher number of WLs. The array 401 may include several such WL groups, although merely two WL groups 478, 479 are illustrated for purposes of illustrative clarity. Also illustrated in FIG. 4A are the pillars 420a, 420b, 420c.

In some embodiments, the integrated WL contact structure 464 has WL contacts 408a, 408b, 408c, 408d, 408e, 408f for WLs 404a, . . . , 404f, respectively. For example, the WL contact 408c extends through the WL contact 408b, the WL contacts 408b extends through the WL contact 408a, and so on. Also illustrates are the isolation materials 412a, . . . , 412e, each of which intervenes between two corresponding WL contacts. The integrated WL contact structure 464 will be apparent to those skilled in the art based on the discussion of various other integrated WL contact structures discussed herein, and hence, the integrated WL contact structure 464 is not discussed in further details. The integrated WL contact structure 465 has similar structure, although individual components of the integrated WL contact structure 465 are not labelled in FIG. 4B for purposes of illustrative clarity.

As illustrated in FIGS. 4A-4B (and as also discussed with respect to FIG. 3A), WLs of a WL group need not be formed as a “staircase.” For example, in FIG. 4B, the ends of the WLs 404a, . . . , 404f can be substantially aligned, or may be slightly misaligned as consequence of process and/or equipment limitations in techniques attendant the formation of the WLs, as discussed with respect to FIGS. 3A-3B.

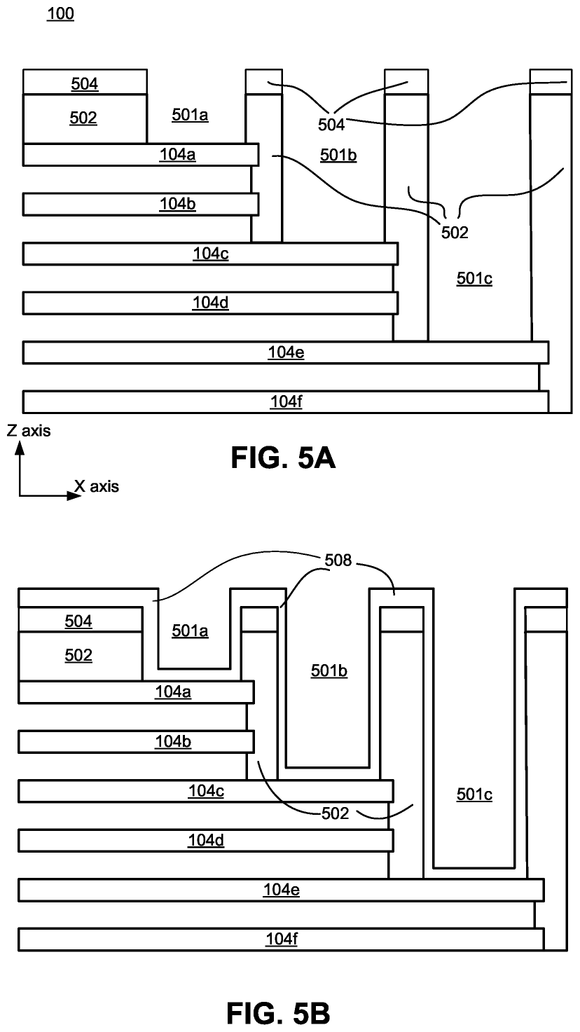

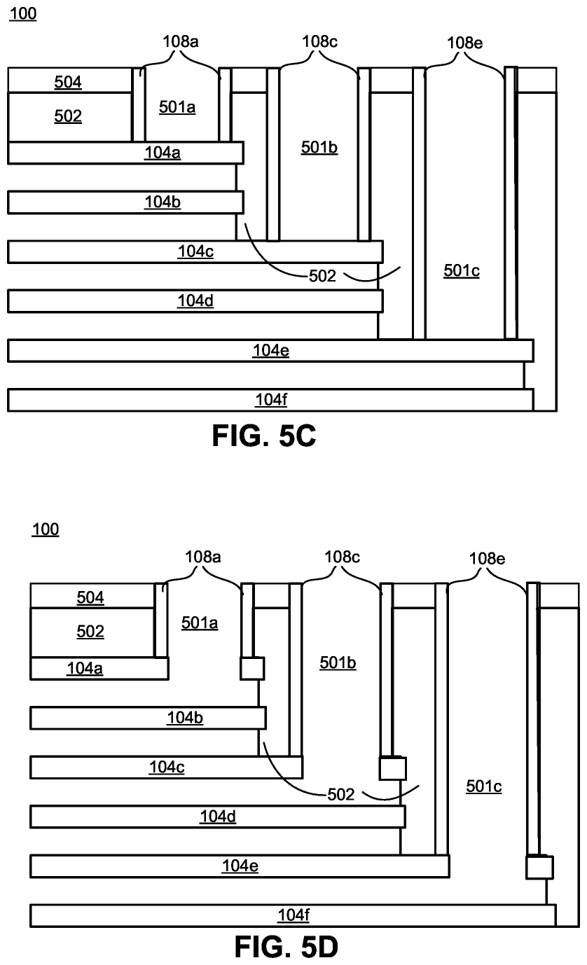

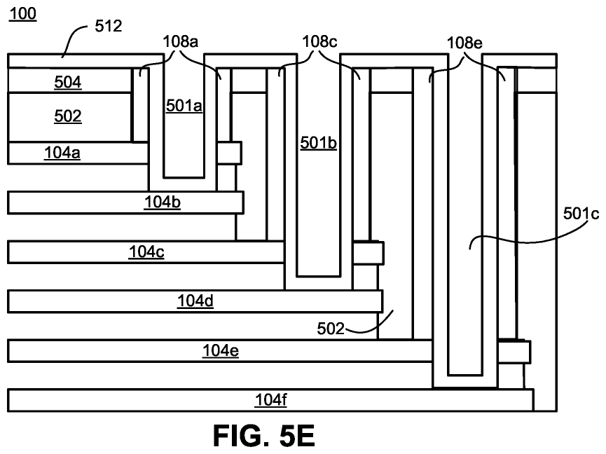

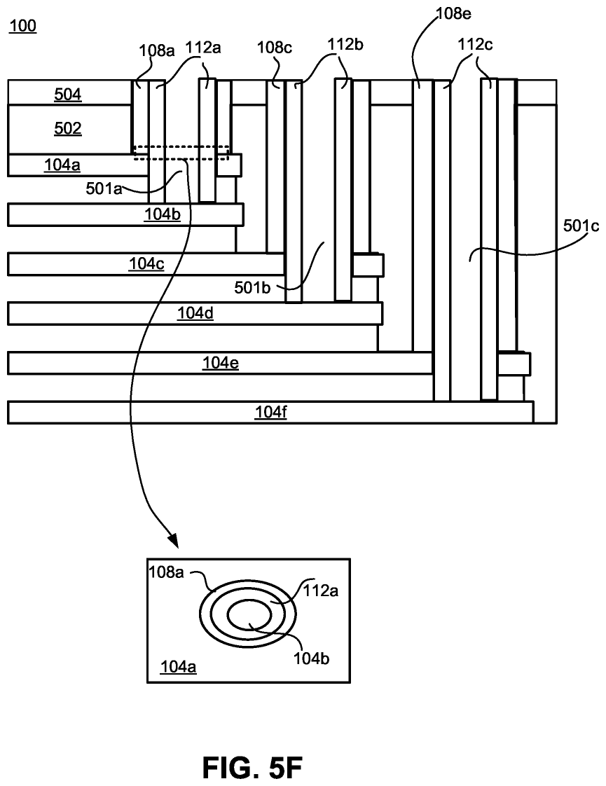

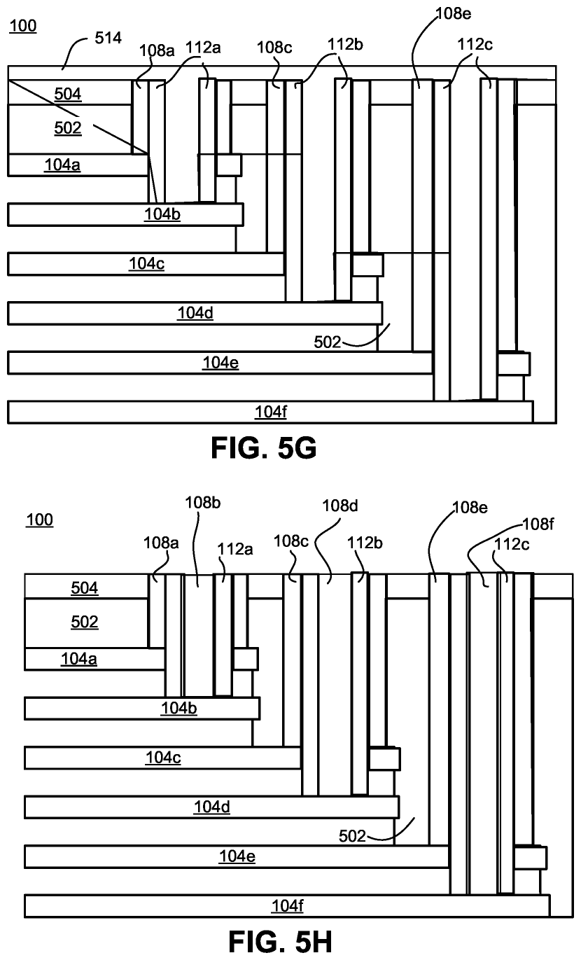

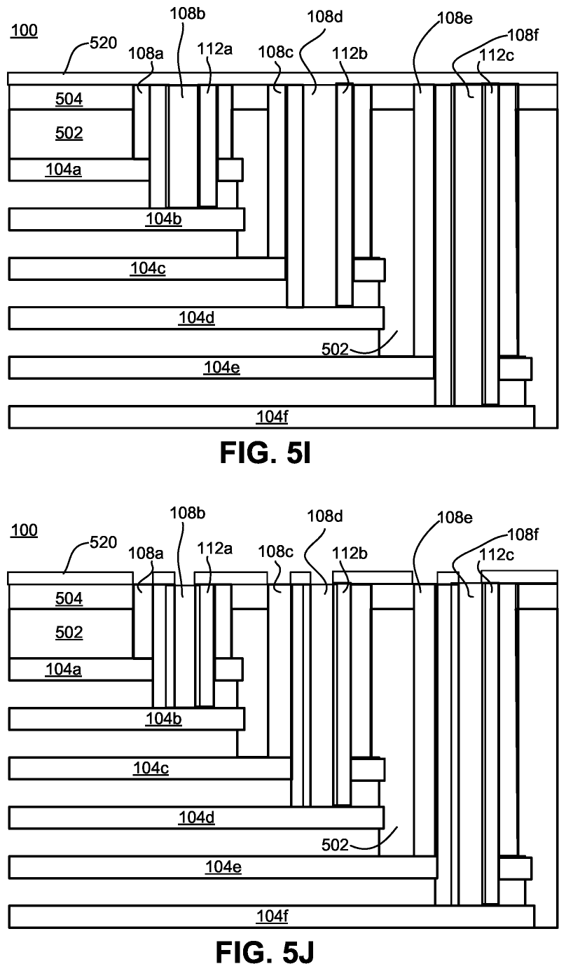

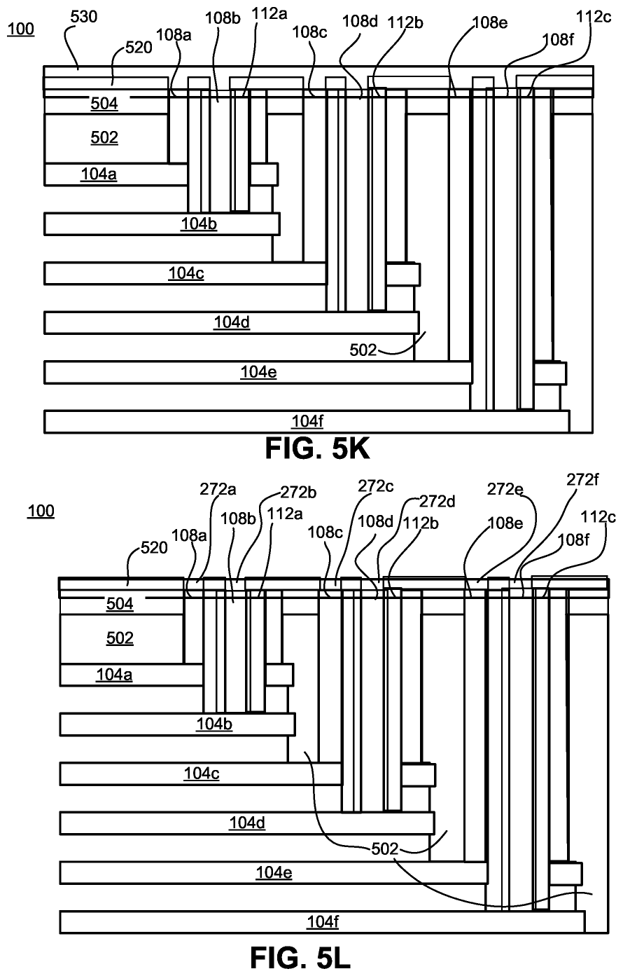

FIGS. 5A, 5B, 5C, 5D, 5E, 5F, 5G, 5H, 5I, 5J, 5K, and 5L collectively illustrate a method for forming integrated WL contact structures for the memory array 100 of FIG. 1, in accordance with some embodiments of this disclosure. These figures illustrate a cross-sectional view of the array 100, and the array 100 is formed. Referring to FIG. 5A, illustrated are the WLs 104a, . . . , 104f. Also illustrated are isolation material 502 and etch stop material 504. Voids 501a, 501b, 501c are defined within the isolation material 502, and individual integrated WL contact structures are to be formed in such voids, as will be discussed in further details herein. Any appropriate isolation material, which are typically used in a memory array, can be used in FIG. 5A. Although not illustrated, the voids 501a, 501b, 501c are formed by depositing the isolation material 502 over the WLs, and selectively etching the isolation material 502.

In FIG. 5B, a layer 508 comprising conductive material is conformally deposited within the voids 501a, 501b, 501c, and over the etch stop layer 504. The conductive material of the layer 508, for example, includes metal and/or any other appropriate conductive material. In some embodiments, the deposition is performed using chemical vapor deposition (CVD), Plasma-enhanced chemical vapor deposition (PE-CVD), atomic layer deposition (ALD), Plasma Enhanced Atomic Layer Deposition (PE-ALD), Physical vapor deposition (PVD), and/or any appropriate deposition technique.

Referring now to FIG. 5C, sections of the layer 508 are etched, such that WL contact 108a is formed on the sidewalls of the void 501a from the layer 508. Similarly, WL contact 108c is formed on the sidewalls of the void 501b, and WL contact 108e is formed on the sidewalls of the void 501c. Thus, sections of the layer 508, which are above the etch stop layer 504 and on bottom sections of the voids 501a, 501b, 501c, are etched. In some embodiments, sections of the layer 508 are etched anisotropically (e.g., dry directional etch).

Referring now to FIG. 5D, sections of the WL 104a, 104c, 104e, which are exposed through the voids 501a, 501b, 501c, respectively, are removed. In some embodiments, sections of the WL 104a, 104c, 104e are etched anisotropically (e.g., dry directional etch). In some embodiments, the etching is selective, such that the exposed WLs are removed, without removal of the WL contacts 108a, 108b, 108c.

Referring now to FIG. 5E, a layer 512 comprising isolation material (such as dielectric material and/or electrically insulating material) is conformally deposited within the voids 501a, 501b, 501c, and over the etch stop layer 504. The isolation material of the layer 512, for example, includes any appropriate isolation material used in a memory array. In some embodiments, the deposition is performed using CVD, PE-CVD, ALD, PE-ALD, PVD, and/or any appropriate deposition technique.

Referring now to FIG. 5F, sections of the layer 512 are etched to form isolation layers 112a, 112b, 112c within the voids 501a, 501b, 501c, respectively. Thus, sections of the layer 512, which are above the etch stop layer 504 and on bottom sections of the voids 501a, 501b, 501c, are etched. In some embodiments, sections of the layer 512 are etched anisotropically (e.g., dry directional etch).

FIG. 5F also illustrates a top-down view of a section of the WL 104a (the section shown using dotted lines). For example, the isolation material 112a is nested within the WL contact 108a. Also, in the top-down view, the lower WL 104b is visible through the void 501a within the isolation material 112a. The top-down views of the WL contact 108a and the isolation material 112a are oval in the example of FIG. 5F—however, any other appropriate shapes may also be possible, as discussed with respect to FIGS. 2A-2c.

Referring now to FIG. 5G, layer 514 comprising conductive material, such as metal, is deposited within the voids 501a, 501b, 501c and on top of the etch stop layer 504. In some embodiments, the deposition is performed using CVD, PE-CVD, ALD, PE-ALD, PVD, and/or any appropriate deposition technique.

Referring now to FIG. 5H, the layer 514 is selectively removed, thereby forming the WL contacts 108b, 108d, and 108f from the layer 514. For example, top sections of the layer 514 are removed. The removal of the top section of the layer 514 may be performed using an appropriate etch operation, a polishing operation (e.g., chemical mechanical polishing (CMP)), and/or an appropriate removal operation.

As previously discussed herein, for example, the WL contact 108b is nested within another WL contact 108a. The inner WL contact 108b resides inside the outer WL contact 108a, and the two WL contacts 108a, 108b are electrically and physically isolated from each other by the isolation material 112a. In some embodiments, the inner WL contact 108b is self-aligned with the outer WL contact 108a. For example, after formation of the outer WL contact 108a in FIGS. 5D, the isolation material 112a is conformally deposited in FIGS. 5E, 5F. Subsequently, the layer 514 is deposited in FIG. 5G, to form the WL contact 108b. Due to the conformal deposition of the isolation material 112a, the WL contact 108b is self-aligned with the WL contact 108a. The inner WL contact 108b is embedded within the outer WL contact 108a.

Referring now to FIG. 5I, a layer 520 comprising insulating material is deposited on top of the array 100, such that the layer 520 blankets the exposed top sections of the WL contacts 108 and the isolation layers 112. In some embodiments, the deposition is performed using CVD, PE-CVD, ALD, PE-ALD, PVD, and/or any appropriate deposition technique. Referring now to FIG. 5J, the layer 520 is patterned to expose parts of the top sections of the WL contacts 108a, . . . , 108f. The remaining portion of the layer 520 still masks the isolation layers 112a, 112b, 112c, as well as the etch stop layer 504.

Referring now to FIG. 5K, a layer 530 comprising conductive material, such as metal, is deposited on top of the array 100, such that the layer 530 blankets the exposed top sections of the WL contacts 108 and the patterned layer 520. In some embodiments, the deposition is performed using CVD, PE-CVD, ALD, PE-ALD, PVD, and/or any appropriate deposition technique.

Referring now to FIG. 5L, a top portion of the layer 530 is removed, e.g., by a polishing operation, such as a CMP operation. The remaining portions of the layer 530 form terminals 272a, . . . , 272f for the WL contacts 108a, . . . , 108f, respectively (the terminals are discussed with respect to FIG. 2E).

The resulting array 100 of FIG. 5L is similar to the array illustrated in FIG. 1. It may be noted that there are some visual differences between the two arrays displayed in FIGS. 1 and 5L. For example, in FIG. 1, the integrated WL contact structures 124 are illustrated to have somewhat tapered shape. Such tapering may be present in the sidewalls of the isolation material 502 in FIG. 5A. Such tapering may be intentional, or may be a consequence of process and/or equipment limitations in techniques attendant the formation of the voids 501a, 501b, 501c using etching within the isolation material 502 in FIG. 5A. Because the WL contacts 108 and the isolation material 112 are deposited conformally, the tapered shape of the voids 501a, 501b, 501c is also propagated to the WL contacts 108 and the isolation material 112, as illustrated in FIG. 1. However, the tapering of various layers is not illustrated in FIGS. 5A-5L, for purposes of illustrative clarity.

Furthermore, the isolation layers 502 separating the integrated WL contact structures 124, as illustrated in FIGS. 5A-5L, are not illustrated in FIG. 1 for purposes of illustrative clarity. Also, although FIG. 5L illustrates the terminals 272a, . . . , 272f, these terminals are not illustrated in FIG. 1 for purposes of brevity. Likewise, the layers 504, 520 illustrated in FIG. 5L are not illustrated in FIG. 1 for purposes of brevity.

FIG. 6A illustrates a memory array 600 comprising WLs 604a, . . . , 604f, and respective WL contacts 608a, . . . , 608f, where none of the WL contacts of FIG. 6A is nested within another WL contact; and FIG. 6B illustrates the memory array 100 of FIG. 1 comprising WLs 104a, . . . , 104f, and respective WL contacts 108a, . . . , 108f, where a WL contact of FIG. 6B is nested within another corresponding WL contact, in accordance with one or more embodiments of the present disclosure. The array 600 of FIG. 6A is similar to a conventional memory array.

In FIG. 6A, illustrated is a pitch P1 of the WL contacts 608, a METE (minimum-end-to-end distance) between two WL contacts, and a critical dimension CD that is a width of a WL contact at its top end. An aspect ratio of a WL contact is a ratio of (i) a depth of the WL contact and (ii) a CD of the WL contact.

In a 3D memory array, WL contact etch relies on a concept of Aspect Ratio Dependent etching (ARDE), to land WL contacts on WLs at different depths at same time. For example, depths of various WL contacts are different, with depth of the WL contact 608f being higher than that of the WL contact 608a.

In an example, it may be beneficial to increase the CD of the deeper contacts. Specifically, it may be beneficial to increase the CD of the deepest contact, i.e., contact 608f in the example of FIG. 6A. For example, increasing the CD of the contact 608f affords a better margin to balance punch through of the shallow contacts and under-etch of the deeper contacts. Put differently, increasing the CD of the deepest contact results in a lower aspect ratio of the deepest contact, thereby making it relatively easier to etch the WL contacts at the deep end. However, in FIG. 6A, the CD of the deepest WL contact is constrained by (i) WL contact pitch P1 (e.g., scaling of which is limited by stair width and die size), and/or (ii) minimum-end-to-end specification, as defined by break down requirements. Thus, these constraints define un upper limit on the CD of the deepest contact 608f, and the CD cannot be increased beyond a threshold value. Put differently, an increase in the maximum CD of the deepest contact impacts (e.g., increases) stair width and/or die size, which may not be desirable.

In contrast, the integrated WL contact structures of the array 100 of FIG. 6B allows an increase in the WL contact CDs, without impacting a die size, and thus, opens up etch margin. For example, in a given integrated WL contact structure (e.g., the integrated WL contact structure 124c), the outer WL contact (e.g., WL contact 108e) is formed by an etch operation. For example, the isolation material 502 has to be etched to form the void 501c in FIG. 5A. The inner WL contact (e.g., WL contact 1080 is simply embedded within the outer WL contact, and thus, the inner WL contact is not formed by an etch operation. As merely one WL contact structure per two WLs are formed, in an example, up to 1.5 times (1.5×) stair width can now be utilized for the etch operation when forming the outer WL contact. Put differently, embedding an inner WL contact within an outer WL contact allows for increase in a CD of the outer WL contact, without a corresponding increase in the width of the WL and/or without a corresponding increase in the size of the memory array. Thus, embedding an inner WL contact within an outer WL contact allows an increase in the CD of the outer and inner WL contacts. For example, FIG. 6B illustrates a top-down view of the integrated WL contact structure 124c, where the CDs of the WL contacts 108e, 108f are illustrated. The CDs of the WL contacts 108e, 108f of FIG. 6B can be made substantially larger than the CD of the WL contact 608f of FIG. 6A, for a same size of the array 100 and 600. Merely as an example, given the same size of the memory arrays 100 and 600, the CD of the WL contact 608f can be about 250 nanometers (nm), whereas the CD of the WL contact 608e can be about 600 nm. Thus, the integrated WL contact structures of the array 100 of FIG. 6B allows an increase in the WL contact CDs, even for the deeper WL contacts. This allows higher margin in modulating the ARDE. Furthermore, the larger CDs of even the deeper WL contacts lead to faster etch of deepest contacts, which results in faster process time and higher margin for the WL etch operation to fabricate the memory array, without any corresponding increase in the memory array size.

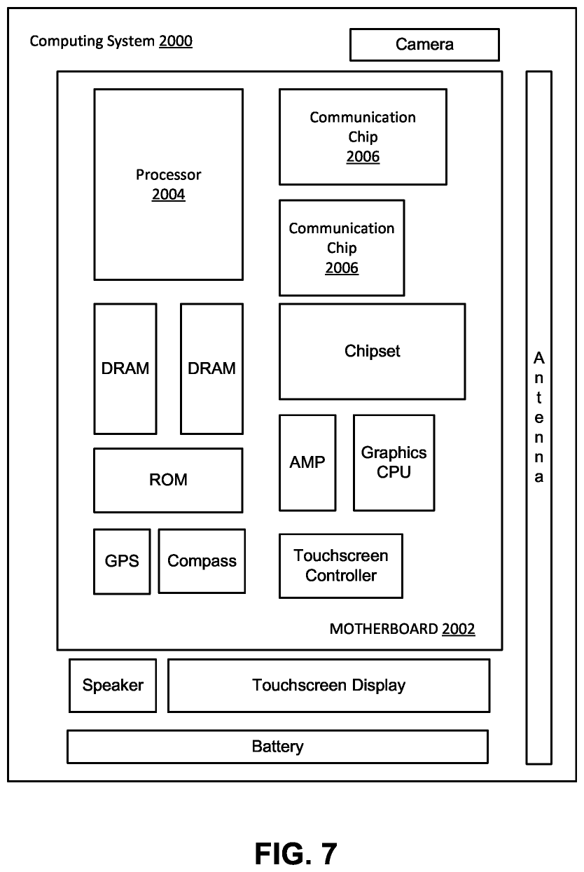

FIG. 7 illustrates an example computing system implemented with memory structures disclosed herein, in accordance with one or more embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board, whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM, flash memory such as 3D NAND flash memory), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). In some embodiments, multiple functions can be integrated into one or more chips (e.g., for instance, note that the communication chip 2006 can be part of or otherwise integrated into the processor 2004).

Any memory, such as any 3D memory (e.g., a 3D flash memory, a 3D NAND flash memory, a 3D NOR memory, or any other appropriate 3D memory discussed in this disclosure), included in computing system 2000 may include one or more memory arrays comprising integrated WL contact structures, as discussed herein.

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices, as variously described herein.

### Further Example Embodiments

Numerous variations and configurations will be apparent in light of this disclosure and the following examples.

Example 1. A memory array comprising: a plurality of word lines (WLs) that includes at least a first WL and a second WL; a first WL contact and a second WL contact for the first WL and the second WL, respectively, wherein the second WL contact extends through the first WL contact; and an isolation structure to isolate the second WL contact from the first WL contact.

Example 2. The memory array of example 1, wherein the second WL contact extends through a hole in the first WL to reach the second WL, and the isolation structure isolates the second WL contact from sidewalls of the hole in the first WL.

Example 3. The memory array of example 2, wherein the isolation structure extends through the hole in the first WL and lands on the second WL.

Example 4. The memory array of any of examples 1-3, wherein: the plurality of WLs forms a staircase WL structure of the memory array; and the second WL is at a lower level of the staircase than the first WL.

Example 5. The memory array of example 4, wherein a length of the second WL contact is greater than a length of the first WL contact.

Example 6. The memory array of any of examples 1-5, wherein the plurality of WLs includes a third WL, and wherein the memory array further comprises: a third WL contact for the third WL, wherein the third WL contact extends through the second WL, and wherein the third WL contact is isolated from the second WL contact by an additional isolation structure.

Example 6A. The memory array of example 6, further comprising: a pillar extending through the first, second, and third WLs; and a plurality of memory cells, wherein each memory cell is at a corresponding junction of a corresponding pillar and a corresponding WL, wherein each of the first, second, and third WLs has (i) a first end near which the pillar extends, and (ii) an opposite second end near which the corresponding WL contact is coupled, and wherein the second ends of the first, second, and third WLs are substantially aligned.

Example 7. The memory array of any of examples 1-6, wherein the plurality of WLs includes a third WL and a fourth WL, and wherein the 3D memory array further comprises: a third WL contact and a fourth WL contact for the third WL and the fourth WL, respectively, wherein the fourth WL contact extends through the third WL contact and the third WL; and an additional isolation structure to isolate the fourth WL contact from third WL contact and the third WL.

Example 8. The memory array of example 7, further comprising: a pillar extending through the plurality of WLs; and a plurality of memory cells, wherein each memory cell is at a corresponding junction of a corresponding pillar and a corresponding WL.

Example 9. The memory array of example 8, wherein: the first, second, and third WLs are WLs of the plurality of WLs; each of the first, second, and third WLs has (i) a first end near which the pillar extends, and (ii) an opposite second end near which the corresponding WL contact is coupled; the second end of the first WL is offset by a first distance with respect to the second end of the second WL; the second end of the second WL is offset by a second distance with respect to the second end of the third WL; and the second distance is greater than the first distance.

Example 10. The memory array of example 9, wherein the second end of the first WL is substantially aligned with the second end of the second WL, such that the first distance is zero or less than 5 nm.

Example 10a. The memory array of any of examples 1-10, wherein the isolation structure comprises one or both of dielectric material or electrically insulating material.

Example 11. The memory array of any of examples 1-10a, wherein the memory array is flash memory array.

Example 12. The memory array of any of examples 1-11, wherein the memory array is three-dimensional (3D) NAND staircase memory array.

Example 13. A motherboard, wherein the memory array of any of examples 1-12 is attached to the motherboard.

Example 14. A computing system comprising the memory array of any of examples 1-13.

Example 15. An integrated circuit memory comprising: a first word line (WL), a second WL, a third WL, and a fourth WL; a pillar extending through the first WL, the second WL, the third WL, and the fourth WL; a first WL contact structure comprising a first WL contact and a second WL contact for the first WL and the second WL, respectively; and a second WL contact structure comprising a third WL contact and a fourth WL contact for the third WL and the fourth WL, respectively.

Example 16. The integrated circuit memory of example 15, wherein the second WL contact is nested within the first WL contact, and wherein the fourth WL contact is nested within the third WL contact.

Example 17. The integrated circuit memory of any of examples 15-16, wherein: the first WL contact structure comprises a first dielectric material to isolate the first WL contact from the second WL contact; and the second WL contact structure comprises a second dielectric material to isolate the third WL contact from the fourth WL contact.

Example 18. The integrated circuit memory of example 17, wherein: the second WL contact extends through a first opening in the first WL, and is isolated from sidewalls of the first opening in the first WL by the first dielectric material; and the fourth WL contact extends through a second opening in the third WL, and is isolated from sidewalls of the second opening in the third WL by the second dielectric material.

Example 19. The integrated circuit memory of any of examples 15-18, further comprising: a fifth WL, wherein the first WL contact structure further comprises a fifth WL contact for the fifth WL.

Example 20. The integrated circuit memory of example 19, wherein: the second WL contact is nested within the first WL contact; and the fifth WL contact is nested within the second WL contact.

Example 21. The integrated circuit memory of example 20, wherein the first WL contact structure further comprises: a first dielectric material to isolate the first WL contact from the second WL contact; and a second dielectric material to isolate the second WL contact from the fifth WL contact.

Example 22. The integrated circuit memory of any of examples 15-21, wherein: the first WL, the second WL, and the third WL are three WLs of the integrated circuit memory; each of the first WL, the second WL, and the third WL has (i) a first end near which the pillar extends, and an opposite second end near which the corresponding WL contact is coupled; the second end of the first WL is offset by a first distance with respect to the second end of the second WL; the second end of the second WL is offset by a second distance with respect to the second end of the third WL; and the second distance is greater than the first distance.

Example 23. The integrated circuit memory of example 22, wherein the first distance is zero or less than 10 nm.

Example 24. The integrated circuit memory of any of examples 15-23, wherein the integrated circuit memory is a three-dimensional (3D) NAND staircase flash memory array.

Example 25. A motherboard, wherein the integrated circuit memory of any of examples 15-24 is attached to the motherboard.

Example 26. A computing system comprising the integrated circuit memory of any of examples 15-25.

Example 27. A method to form a memory array, the method comprising: forming a first word line (WL) and a second WL; forming a first WL contact that is coupled to the first WL, wherein a first through-hole extends through the first WL contact and the first WL; forming a dielectric layer within sidewalls of the first through-hole, wherein a second through-hole extends through the dielectric layer; and depositing conductive material within the second through-hole to form a second WL contact, such that the second WL contact (i) extends through the first WL contact and the first WL, and (ii) is isolated from the first WL contact and the first WL by the dielectric layer.

Example 28. The method of example 27, wherein the dielectric layer is a first dielectric layer, and wherein forming the first WL contact comprises: forming a second dielectric layer over the first WL; etching the second dielectric layer to form an opening that exposes the first WL; and conformally depositing conductive material on sidewalls of the first dielectric layer through the opening, to form the first WL contact, wherein the first through-hole extends through the first WL contact.

Example 29. The method of example 28, wherein a section of the first WL is exposed through the first through-hole, and wherein the method further comprises: removing the section of the first WL, such that the first through-hole extends through the section of the first WL.

Example 30. The method of example 28, wherein the second WL contact extends through the first WL contact and the first WL, and is in physical contact with the second WL.

Example 31. The method of any of examples 27-30, wherein a third through-hole extends through the second WL contact, wherein the dielectric layer is a first dielectric layer, and wherein the method comprises: forming a second dielectric layer within sidewalls of the third through-hole, wherein a fourth through-hole extends through the second dielectric layer; and depositing another conductive material within the fourth through-hole to form a third WL contact, such that the third WL contact (i) extends through the second WL contact and the second WL, and (ii) is isolated from the second WL contact and the second WL by the second dielectric layer.

The foregoing detailed description has been presented for illustration. It is not intended to be exhaustive or to limit the disclosure to the precise form described. Many modifications and variations are possible in light of this disclosure. Therefore it is intended that the scope of this application be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1-20. (canceled)

21. A memory array comprising:
a plurality of word lines (WLs) in a vertical stack, including at least a first WL, a second WL, and a third WL;
a first WL insulating layer between the first WL and the second WL to electrically isolate the first WL from the second WL;
a second WL insulating layer between the second WL and the third WL to isolate the second WL from the third WL;
a first WL contact, a second WL contact, and a third WL contact in physical contact with the first WL, the second WL, and the third WL, respectively, wherein the second WL contact extends through the first WL contact and the third WL contact extends vertically through the first WL contact and through the second WL contact;
a first isolation structure to isolate the second WL contact from the first WL contact, extend through the first WL, and end where a bottom section of the first WL meets a top section of the first WL insulating layer; and
a second isolation structure to isolate the third WL contact from the second WL contact, extend through the second WL, and end where a bottom section of the second WL meets a top section of the second WL insulating layer.

22. The memory array of claim 21, wherein the second WL contact extends through a hole in the first WL to reach the second WL, and the first isolation structure isolates the second WL contact from sidewalls of the hole in the first WL.

23. The memory array of claim 21, wherein:
the plurality of WLs forms a staircase structure; and
the second WL is at a lower level of the staircase structure than the first WL.

24. The memory array of claim 23, wherein a length of the second WL contact is greater than a length of the first WL contact.

25. The memory array of claim 21, wherein the first isolation structure and the second isolation structure comprise a dielectric material.

26. The memory array of claim 21, wherein the memory array is a three-dimensional (3D) NAND staircase memory array, or a 3D NOR staircase memory array.

27. A computing system comprising:
a processor; and
a memory array including:
a plurality of word lines (WLs) in a vertical stack, including at least three WLs: a first WL, a second WL, and a third WL;
a first WL insulating layer between the first WL and the second WL to electrically isolate the first WL from the second WL;
a second WL insulating layer between the second WL and the third WL to isolate the second WL from the third WL;
a first WL contact, a second WL contact, and a third WL contact in physical contact with the first WL, the second WL, and the third WL, respectively, wherein the second WL contact extends through the first WL contact and the third WL contact extends through the first WL contact and the second WL contact;
a first isolation structure to isolate the second WL contact from the first WL contact, extend through the first WL, and end where a bottom section of the first WL meets a top section of the first WL insulating layer; and
a second isolation structure to isolate the third WL contact from the second WL contact, extend through the second WL, and end where a bottom section of the second WL meets a top section of the second WL insulating layer.

28. The computing system of claim 27, wherein the second WL contact extends through a hole in the first WL to reach the second WL, and the first isolation structure isolates the second WL contact from sidewalls of the hole in the first WL.

29. The computing system of claim 27, wherein:
the plurality of WLs forms a staircase structure; and
the second WL is at a lower level of the staircase structure than the first WL.

30. The computing system of claim 27, wherein a length of the second WL contact is greater than a length of the first WL contact.

31. The computing system of claim 27, wherein the first isolation structure and the second isolation structure comprise a dielectric material.

32. The computing system of claim 27, wherein the memory array is a three-dimensional (3D) NAND staircase memory array or a 3D NOR staircase memory array.

33. The memory array of claim 22, wherein the third WL contact extends through the hole in the first WL and a hole in the second WL to reach the third WL, and the second isolation structure isolates the third WL contact from sidewalls of the hole in the second WL.

34. The memory array of claim 23, further comprising:
a pillar extending through the first WL, the second WL, and the third WL; and
a plurality of memory cells, each of the memory cells located at a corresponding junction of the pillar with a corresponding WL;
wherein the staircase structure is formed in part by the second WL extending further than an end of the first WL, and the third WL extending further than an end of the second WL.

35. The memory array of claim 34, wherein the second WL extends further than the end of the first WL by a distance less than 5 nm and wherein the third WL extends further than the end of the second WL by a distance less than 5 nm.

36. The memory array of claim 23, further comprising:
a pillar extending through the first WL, the second WL, and the third WL; and
a plurality of memory cells, each of the memory cells located at a corresponding junction of the pillar with a corresponding WL;
wherein an end of the first WL, an end of the second WL, and an end of the third WL are substantially aligned; and
wherein the first WL, the second WL, and the third WL form a first WL group, the staircase structure formed in part by a second WL group lower in the staircase structure extending farther than the end of the first WL, the end of the second WL, and the end of the third WL.

37. The computing system of claim 28, wherein the third WL contact extends through the hole in the first WL and a hole in the second WL to reach the third WL, and the second isolation structure isolates the third WL contact from sidewalls of the hole in the second WL.

38. The computing system of claim 29, the memory array further comprising:
a pillar extending through the first WL, the second WL, and the third WL; and
a plurality of memory cells, each of the memory cells located at a corresponding junction of the pillar with a corresponding WL;
wherein the staircase structure is formed in part by the second WL extending further than an end of the first WL, and the third WL extending further than an end of the second WL.

39. The computing system of claim 38, wherein the second WL extends further than the end of the first WL by a distance less than 5 nm and wherein the third WL extends further than the end of the second WL by a distance less than 5 nm.

40. The computing system of claim 29, the memory array further comprising:
a pillar extending through the first WL, the second WL, and the third WL; and
a plurality of memory cells, each of the memory cells located at a corresponding junction of the pillar with a corresponding WL;
wherein an end of the first WL, an end of the second WL, and an end of the third WL are substantially aligned; and
wherein the first WL, the second WL, and the third WL form a first WL group, the staircase structure formed in part by a second WL group lower in the staircase structure extending farther than the end of the first WL, the end of the second WL, and the end of the third WL.
